(19) United States
(12) Patent Application Publication
(10) Pub. No.: US 2014/0342292 A1
(43) Pub. Date: Nov. 20, 2014

(54) DI-T-BUTOXYDIACETOXYSILANE-BASED SILSESQUIOXANE RESINS AS HARD-MASK ANTIREFLECTIVE COATING MATERIAL AND METHOD OF MAKING

(71) Applicant: Dow Corning Corporation, Midland, MI (US)

(72) Inventors: Peng-Fei Fu, Midland, MI (US); Eric S. Moyer, Midland, MI (US); Jason Suhr, Coleman, MI (US)

(21) Appl. No.: 14/370,230

(22) PCT Filed: Jan. 8, 2013
(86) PCT No.: PCT/US2013/020617

§ 371 Date: Jul. 2, 2014

Related U.S. Application Data
(60) Provisional application No. 61/584,448, filed on Jan. 9, 2012.

(51) Int. Cl. C08G 77/04; H01L 21/027; G03F 7/16

(52) U.S. Cl. CPC C08G 77/04; G03F 7/162; G03F 7/168; H01L 21/0276
USPC 430/325; 528/20; 438/780

(57) ABSTRACT

A method of preparing a DIABS-based silsesquioxane resin for use in an antireflective hard-mask coating for photolithography is provided. Methods of preparing an antireflective coating from the DIABS-based silsesquioxane resin and using said antireflective coating in photolithography is alternatively presented. The DIABS-based silsequioxane resin has structural units formed from the hydrolysis and condensation of silane monomers including di-t-butoxydiacetoxysilane (DIABS) and at least one selected from the group of R¹ SiX₃, R²SiX₃, R³SiX₃, and SiX₄ with water; wherein R¹ is H or an alkyl group, X is a halide or an alkoxy group, R² is a chromophore moiety, and R³ is a reactive site or crosslinking site. The DIABS-based silsesqioxane resin is characterized by the presence of at least one tetra-functional SiO_{4/2} unit formed via the hydrolysis of di-t-butoxydiacetoxysilane (DIABS).

This disclosure relates generally to photolithography. More specifically, this disclosure relates to the preparation of di-t-butoxydiacetoxysilane-based silsesquioxane resins and their use as hard-mask antireflective coatings on an electronic device during 193 nm photolithographic processing.

With the continuing demand for smaller feature sizes in the semiconductor industry, photolithography using 193 nm light has recently emerged as a technology capable of producing devices with sub-100 nm features. The use of such a short wavelength of light requires the inclusion of a bottom antireflective coating capable of reducing the occurrence of reflecting light onto the substrate, as well as damping of the photoresist swing cure by absorbing light that passes though the photoresist. Antireflective coatings (ARCs) consisting of organic or inorganic based materials are commercially available. Conventional inorganic ARCs, which exhibit good etch resistance, are typically deposited using a chemical vapor deposition (CVD) process. Thus, these inorganic ARCs are subject to all of the integration disadvantages associated with extreme topography. On the other hand, conventional organic ARCs are typically applied using spin-on processes. Thus, organic ARCs exhibit excellent fill and planarization properties, but suffer from poor etch selectivity when used as an organic photoresist. As a result, the development of new materials that offer the combined advantages of organic and inorganic ARCs is continually desirable.

One type of antireflective coating used in 193 nm photolithography that combines the advantages of organic and inorganic ARCs comprising silsesquioxane resins having one or more tetra-functional SiO_{4/2} (Q) units. Such tetra-functional Q units are conventionally formed in the silsequioxane resins through the hydrolysis and condensation of tetrachlorosilane or tetraalkoxysilane monomers, such as tetraethoxysilane (TEOS) and tetramethoxysilane (TMOS). Unfortunately, the silsesquioxane resins made using these monomers typically exhibit poor stability and a short shelf-life when stored either in solution or as “dry” solid. In addition, the aging of these silsesquioxane resins may lead to the occurrence of a greater number of film defects when they are coated onto silicon wafers. The existence of these shortcomings prevents conventional silsesquioxane resins from becoming qualified as a hard-mask ARC material for use in a 193 nm photolithographic process.

### BRIEF SUMMARY OF THE INVENTION

In overcoming the enumerated drawbacks and other limitations of the related art, the present disclosure generally provides a method of preparing an antireflective hard-mask coating for use in photolithography, wherein the composition of the antireflective hardmask coating is characterized by the presence of a tetra-functional SiO_{4/2} unit formed via the hydrolysis of di-t-butoxydiacetoxysilane (DIABS).

According to one aspect of the present disclosure, a method for preparing a DIABS-based silsesquioxane resin for use in the hardmask antireflective coating is provided. This method generally comprises the steps of: providing silane monomers in a solvent to form a reaction mixture; adding water to the reaction mixture and allowing hydrolysis and condensation reactions to occur in order to form the structural units of the DIABS-based silsesquioxane resin; forming a DIABS-based silsesquioxane resin solution; removing volatiles from the DIABS-based silsesquioxane resin solution; and adjusting the resin to solvent ratio, such that the DIABS-based silsesquioxane resin is in a predetermined concentration. The silane monomers used to form the DIABS-based silsesquioxane resin include DIABS and at least one selected from the group of R¹SiX₃, R²SiX₃, R³SiX₃, and SiX₄, wherein R¹ is H or an alkyl group, X is a halide or an alkoxy group, R² is a chromophore moiety, and R³ is a reactive site or crosslinking site. The DIABS-based silsesquioxane resin includes at least one structural unit being an SiO_{4/2} unit that arises from the hydrolysis and condensation of the DIABS monomers.

According to another aspect of the present disclosure, a method of preparing an antireflective coating for use in photolithography is provided. This method generally comprises the steps of: providing an ARC material that includes a DIABS-based silsesquioxane resin dispersed in a solvent; providing an electronic device; applying the ARC material to the surface of the electronic device to form a film; removing the solvent from the film; and curing the film to form the antireflective coating. The DIABS-based silsequioxane resin comprises structural units formed from the hydrolysis and condensation of silane monomers that include DIABS and at least one selected from the group of R¹ SiX₃, R²SiX₃, R³SiX₃, and SiX₄ with water; wherein R¹ is H or an alkyl group, X is a halide or an alkoxy group, R² is a chromophore moiety, and R³ is a reactive site or crosslinking site. The DIABS-based silsesquioxane resin includes at least one structural unit that is a SiO_{4/2} unit arising from the hydrolysis and condensation of the DIABS monomers.

According to yet another aspect of the present disclosure, a method of performing photolithography using a DIABS-based silsequioxane resin in an antireflective coating is provided. This method generally comprises the steps of: forming an antireflective coating on a substrate; forming a resist coating over the antireflective coating; exposing the resist to radiation to form a pattern on the resist; and developing the resist and the antireflective coating. The antireflective coating comprises a DIABS-based silsesquioxane resin having structural units formed from the hydrolysis and condensation of silane monomers including DIABS and at least one selected from the group of R¹ SiX₃, R²SiX₃, R³SiX₃, and SiX₄ with water; wherein R¹ is H or an alkyl group, X is a halide or an alkoxy group, R² is a chromophore moiety, and R³ is a reactive site or crosslinking site. The DIABS-based silsesquioxane resin includes at least one structural unit that is a SiO_{4/2} unit arising from the hydrolysis and condensation of the DIABS monomers.

According to yet another aspect of the present disclosure, the DIABS-based silsesquioxane resin formed using the method described herein may be described by components A, B, C, and D according to the formula [A]ₘ[B]ₙ[C]ₒ[D]ₚ; wherein the subscripts m, n, o, and p represent the mole fraction of each component in the resin with each subscript being independently selected to range between 0 and about 0.95, provided that the sum of the subscripts (m+n+o+p) is equal to 1. In this formula, [A] represents structural units of [(SiO_{(4-x)/2}(OR)ₓ)], [B] represents structural units of [(Ph(CH₂)ᵣSiO_{(3-x/2}(OR)ₓ], [C] represents structural units of [(RO)ₓO_{(3-x)/2}Si—CH₂CH₂—SiO_{(3-x)/2}(OR)ₓ], and [D] represents structural units of [R′SiO_{(3-x)/2}(OR)ₓ]; wherein R is independently selected as a t-butyl group, a hydrogen, or a hydrocarbon group having from 1 to 4 carbon atoms; Ph is a phenyl group; and R′ is independently selected as a hydrocarbon group, a substituted phenyl group, an ester group, a polyether group, a mercapto group, or a reactive (e.g., curable) organic functional group. The subscripts r and x are independently selected such that r has a value of 0, 1, 2, 3, or 4 and x has a value of 0, 1, 2, or 3.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic representation of a method for preparing DIABS-based silsesquioxane resins according to the teachings of the present disclosure;

FIG. 2 is a schematic representation of a method for preparing an antireflective coating using the DIABS-based silsesquioxane resins of FIG. 1; and

FIG. 3 is a schematic representation of a photolithographic process using the DIABS-based silsequioxane resins of FIG. 1 in the antireflective coating of FIG. 2.

### DETAILED DESCRIPTION

The following description is merely exemplary in nature and is in no way intended to limit the present disclosure or its application or uses. It should be understood that throughout the description and drawings, corresponding reference numerals indicate like or corresponding parts and features.

The present disclosure generally provides an antireflective hard-mask coating composition for use in photolithography. The composition of the antireflective hardmask coating is characterized by the presence of a tetra-functional SiO_{4/2} unit formed via the hydrolysis of di-t-butoxydiacetoxysilane (DIABS) having the formula (^{t}BuO)₂Si(OAc)₂. The antireflective hardmask composition is alternatively a siloxane or silsesquioxane polymer containing chromophore moieties. In general, the polymer contains structural units from the hydrolysis of DIABS and one or more silicon monomers selected from R¹SiX₃, R²SiX₃, R³SiX₃, and SiX₄, wherein R¹ is H, an alkyl group having 1-20 carbon atoms,; X is a halide or an alkoxy group, for example, X is a Cl, OR⁴, OR⁴ group, where R⁴ is a methyl, ethyl, or propyl group; R² is a chromophore moiety, for example, R² is a phenyl or substituted phenyl group, such as an ethylphenyl group and R³ comprises a reactive site or crosslinking site for the spin-on film to be cured under the conditions applied.

When DIABS is used as the monomer for making the tetra-functional SiO_{4/2} (Q unit) containing silsesquioxane materials, the stability of the resulted resin as a hard-mask ARC is greatly improved and the film defect level is also greatly reduced, making it an ideal material for the targeted 193 nm photolithography application, in comparison with the materials conventionally formed through the hydrolysis and condensation of tetrachlorosilane or tetraalkoxysilane monomers, such as tetraethoxysilane (TEOS) and tetramethoxysilane (TMOS). These DIABS-based silsesquioxane compositions offer: (1) outstanding optical, mechanical and etch properties and can be applied by spin-on techniques; (2) great shelf-life and stability on storage; and (3) good film quality with great solvent (e.g. PGMEA) and developer (e.g., TMAH) resistant after cure for 1 minute at a temperature up to about 250° C. The cured ARC shows no defects or a small, limited number of defects.

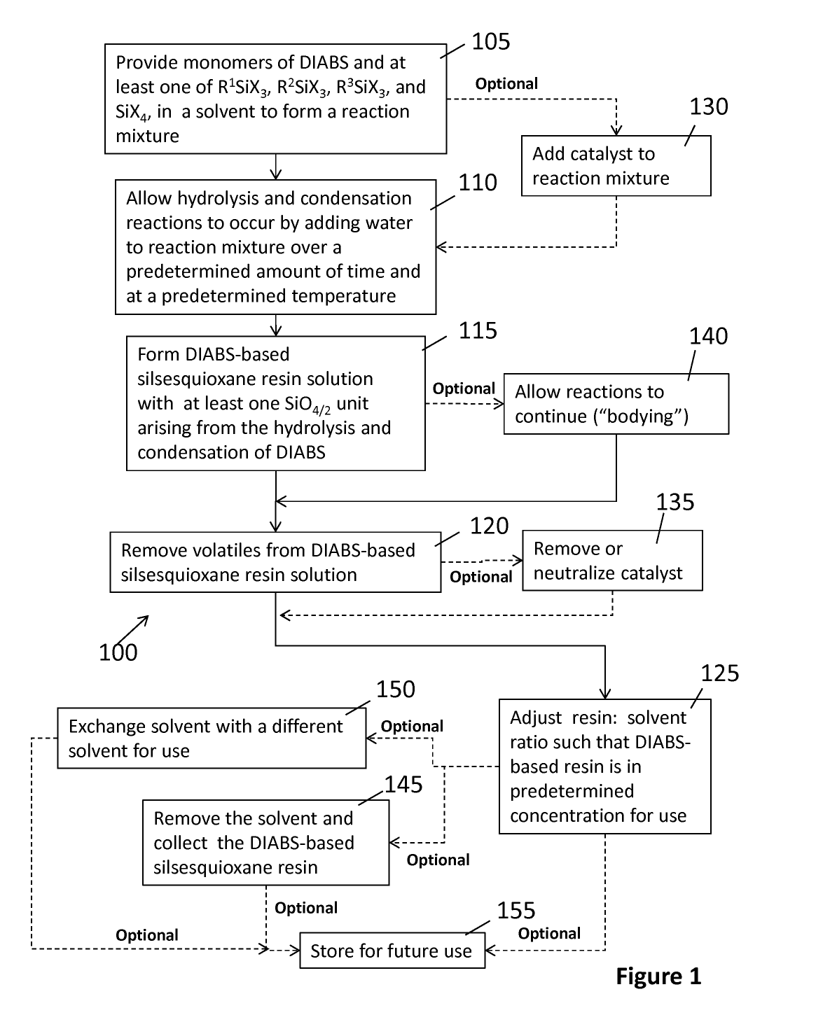

According to one aspect of the present disclosure, a method of preparing DIABS-based silsesquioxane resins for use as an ARC material is provided. Referring to FIG. 1 depicting method 100, DIABS monomers and at least one other type of silane monomer are provided in a solvent to form a reaction mixture (105). The reaction mixture is then allowed to undergo hydrolysis and condensation reactions upon the addition of water over a predetermined amount of time and at a predetermined temperature (110) to form a DIABS-based silsesquioxane resin solution in which the silsesquioxane comprises at least one SiO_{4/2} unit arising from the hydrolysis and condensation of the DIABS (115). When desirable any volatiles in the DIABS-based silsesquioxane resin solution are subsequently removed (120) and the amount of solvent present in the solution reduced such that the concentration of the resin is at a predetermined amount (125); alternatively, the predetermined amount is the concentration desired for further use. Additional information regarding the method for producing the silsesquioxane resins involving the hydrolysis and condensation of appropriate halo and/or alkoxy silanes is provided below and in U.S. Pat. No. 5,762,697 to Sakamoto et al., U.S. Pat. No. 6,281,285 to Becker et al. and U.S. Pat. No. 5,010,159 to Bank et al., the disclosure of which is incorporated herein by reference. One specific example of a method according to the teachings of the present disclosure involves the hydrolysis and condensation of a mixture of DIABS with phenyltrichlorosilane and optionally other organofunctional trichlorosilanes.

The DIABS-based silsesquioxane resins prepared according to the method 1 of the present disclosure exhibit a weight average molecular weight (Mw) in the range of 500 to 400,000 alternatively in the range of 500 to 100,000, alternatively in the range of 700 to 30,000 as determined by gel permeation chromatography employing refractive index (RI) detection and polystyrene standards.

The amount of water present during the hydrolysis reaction is typically in the range of 0.5 to 2 moles water per mole of X groups in the silane reactants, alternatively 0.5 to 1.5 moles per mole of X groups in the silane reactants. It is possible that residual —OH and/or —OR⁴ will remain in the DIABS-based silsesquioxane resin as a result of incomplete hydrolysis or condensation.

The time to form the silsesquioxane resin is dependent upon a number of factors such as the temperature, the type and amount of silane reactants, and the amount of catalyst, if present. The reaction is allowed to proceed for a time that is sufficient for essentially all of the X groups to undergo hydrolysis reactions. Typically the reaction time is from minutes to hours, alternatively 10 minutes to 1 hour. One skilled in the art will be able to readily determine the time necessary to complete the reaction.

The reaction to produce the DIABS-based silsesquioxane resins can be carried out at any temperature so long as it does not cause significant gellation or curing of the silsesquioxane resin. The temperature at which the reaction is carried out is typically in the range of 25° C. up to the reflux temperature of the reaction mixture. The reaction may be carried out by heating under reflux for 10 minutes to 1 hour.

Still referring to FIG. 1, in order to facilitate the completion of the hydrolysis and condensation reaction a catalyst may optionally be used (130) when desired. The catalyst can be a base or an acid such as a mineral acid. Useful mineral acids include, but are not limited to, HCl, HF, HBr, HNO₃, and H₂SO₄, among others, alternatively the mineral acid is HCl. The benefit of using HCl or another volatile acid is that a volatile acid can be easily removed from the composition by a stripping process after the reaction is completed. The amount of catalyst used to facilitate the reaction may depend on its nature. The amount of catalyst is typically about 0.05 wt. % to about 1 wt. % based on the total weight of the reaction mixture.

Generally, the silane reactants are either not soluble in water or sparingly soluble in water. In light of this, the reaction is carried out in a solvent. The solvent is present in any amount sufficient to dissolve the silane reactants. Typically the solvent is present from 1 to 99 weight percent, alternatively from about 70 to 90 wt. % based on the total weight of the reaction mixture. Useful organic solvents may be exemplified by, but not limited to, saturated aliphatics such as n-pentane, hexane, n-heptane, and isooctane; cycloaliphatics such as cyclopentane and cyclohexane; aromatics such as benzene, toluene, xylene, mesitylene; ethers such as tetrahydrofuran, dioxane, ethylene glycol diethyl ether, ethylene glycol dimethyl ether; ketones such as methylisobutyl ketone (MIBK) and cyclohexanone; halogen substituted alkanes such as trichloroethane; halogenated aromatics such as bromobenzene and chlorobenzene; esters such as propylene glycol monomethyl ether acetate (PGMEA), isobutyl isobutyrate and propyl propionate. Useful silicone solvents may be exemplified by, but not limited to cyclic siloxanes such as octamethylcyclotetrasiloxane, and decamethylcyclopentasiloxane. A single solvent may be used or a mixture of solvents may be used.

In the process for making the DIABS-based silsesquioxane resins, after the reaction is complete, volatiles may be removed (120) from the silsesquioxane resin solution under reduced pressure when desirable. Such volatiles include alcohol by-products, excess water, catalyst, hydrochloric acid (chlorosilanes routes) and solvents. Methods for removing volatiles are known in the art and include, for example, distillation or stripping under reduced pressure.

Following completion of the reaction, the catalyst may be optionally removed (135). Methods for removing the catalyst are well known in the art and include neutralization, stripping or water washing or combinations thereof. The catalyst may negatively impact the shelf life of the DIABS-based silsesquioxane resin especially when in solution. To increase the molecular weight of the DIABS-based silsesquioxane resin and/or to improve the storage stability of the silsesquioxane resin, the reaction may be carried out for an extended period of time (140) with heating from 40° C. up to the reflux temperature of the solvent (“bodying step”). The bodying step 140 may be carried out subsequent to the reaction step or as part of the reaction step. Typically, the bodying step is carried out for a period of time in the range of 10 minutes to 6 hours, alternatively 20 minutes to 3 hours.

Following the reaction to produce the silsesquioxane resin, a number of optional steps may be carried out to obtain the silsesquioxane resin in the desired form. For example, the silsesquioxane resin may be recovered in solid form by removing the solvent (145). The method of solvent removal is not critical and numerous methods are well known in the art (e.g. distillation under heat and/or vacuum). Once the silsesquioxane resin is recovered in a solid form after step 145, the resin can be optionally re-dissolved in the same or another solvent for a particular use. Alternatively, if a different solvent, other than the solvent used in the reaction, is desired for the final product, a solvent exchange (150) may be done by adding a secondary solvent and removing the first solvent through distillation, for example. Additionally, the resin concentration in solvent can be adjusted (125) by removing some of the solvent or adding additional amounts of solvent.

According to another aspect of the present disclosure, the composition of the DIABS-based silsesquioxane resin formed using the method described above may be described to comprise components A, B, C, and D according to the relationship or formula [A]ₘ[B]ₙ[C]ₒ[D]ₚ; where the subscripts m, n, o, and p represent the mole fraction of each component in the resin with each subscript being independently selected to range between 0 and 0.95, provided that the sum of the subscripts (m+n+o+p) is equal to 1. In this formula, component [A] represents [(SiO_{(4-x)/2}(OR)ₓ)] structural units, component [B] represents structural units of [(Ph(CH₂)ᵣSiO_{(3-x)/2}(OR)ₓ], component [C] represents structural units of [(RO)ₓO_{(3-x)/2}Si—CH₂CH₂—SiO_{(3-x)/2}(OR)ₓ], and component [D] represents structural units of [R′SiO_{(3-x)/2}(OR)ₓ]; wherein R is independently selected as a t-butyl group, a hydrogen, or a hydrocarbon group having from 1 to 4 carbon atoms; Ph is a phenyl group; and R′ is independently selected as a hydrocarbon group, a substituted phenyl group, an ester group, a polyether group, a mercapto group, or a reactive (e.g., curable) organic functional group. The subscripts r and x are independently selected such that r has a value of 0, 1, 2, 3, or 4 and x has a value of 0, 1, 2, or 3. At least one of the structural units present in the DIABS-based silsesquioxane resin is derived or formed from the hydrolysis and condensation reaction of DIABS monomers. Alternatively, the structural units of component A in the resin is derived or formed from the hydrolysis and condensation reaction of DIABS monomers.

According to another aspect of the present disclosure, the DIABS-based silsequioxane resin is applied as an antireflective coating (ARC) material for use in a photolithographic process. The silsesquioxane resin is typically applied from a solvent. Useful solvents include, but are not limited to, 1-methoxy-2-propanol, propylene glycol monomethyl ethyl acetate, gamma-butyrolactone, and cyclohexanone, among others. The ARC material typically comprises from 10% to 99.9 wt. % solvent based on the total weight of the ARC material, alternatively 80 to 95 wt. %.

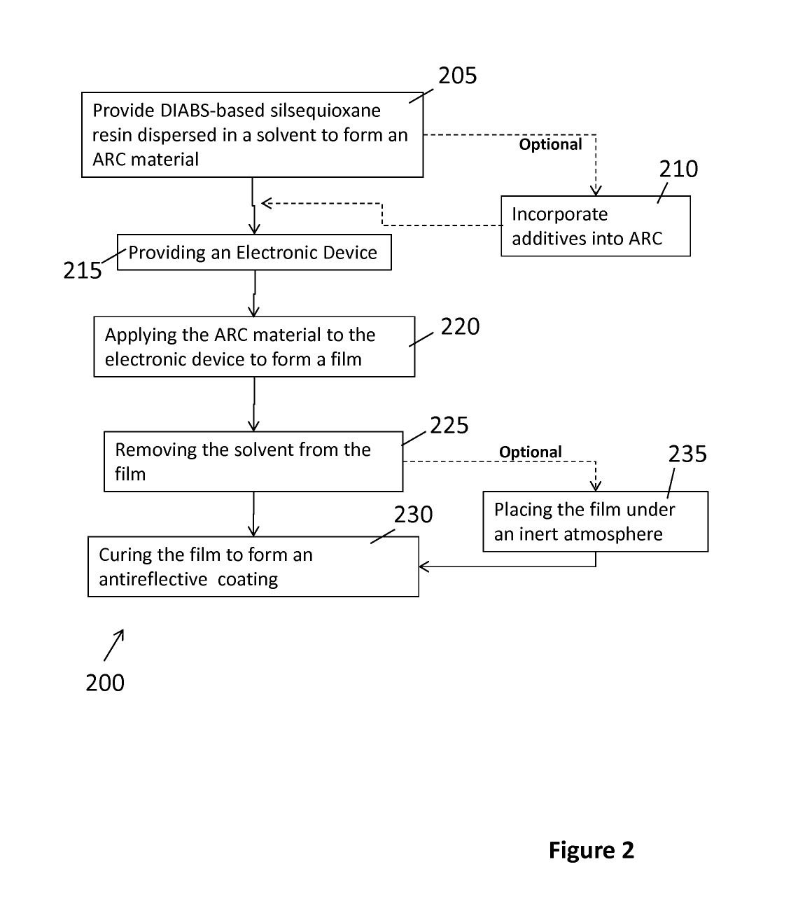

Referring to FIG. 2 depicting process (200), the antireflective coating material is formed by providing a DIABS-based silsesquioxane resin in a solvent at a predetermined concentration (205). Optionally, additional or other additive(s) may be incorporated into the ARC material (210). An electronic device is then provided (215) upon which the antireflective coating is subsequently formed. The method 100 further includes applying the ARC material to the electronic device to form a film (220), removing the solvent from the film (225); and curing the DIABS-based silsesquioxane resin film to form an antireflective coating on the device (230).

An example of an additive that may be optionally added or incorporated into the ARC material at step 210 is a cure catalyst. Suitable cure catalysts include inorganic acids, photo-acid generators and thermal acid generators. Cure catalysts may be exemplified by, but not limited to, sulfuric acid (H₂SO₄), (4-ethylthiophenyl) methyl phenyl sulfonium trifluoromethanesulfonate (also called triflate), and 2-naphthyl diphenylsulfonium triflate. Typically a cure catalyst is present in an amount of up to about 1000 ppm, alternatively up to about 500 ppm, based on the total weight of the ARC material.

The electronic device may be a semiconductor device, such as a silicon-based device and a gallium arsenide-based device intended for use in the manufacture of a semiconductor component. Typically, the device comprises at least one semiconductive layer and a plurality of other layers comprising various conductive, semiconductive, or insulating materials.

Specific examples of processes useful in applying the ARC material to the electronic device at step 220 include, but are not limited to, spin-coating, dip-coating, spay-coating, flow-coating, and screen printing, among others. In one instance, the method for application is spin coating. Typically, the application of the ARC material involves spinning the electronic device, at 1,000 to 2,000 RPM, and adding the ARC material to the surface of the spinning device.

The solvent may be removed from the film (225) using any method known to one skilled in the art, including but not limited to “drying” at room temperature or at an elevated temperature for a predetermined amount of time. The “dry” film is subsequently cured to form the antireflective coating on the electronic device (230). Curing step 230 generally comprises heating the coating to a sufficient temperature for a sufficient duration to lead to sufficient crosslinking such that the silsesquioxane resin is essentially insoluble in the solvent from which it was applied. Curing step 230 may take place, for example, by heating the coated electronic device at about 80° C. to 450° C. for about 0.1 to 60 minutes, alternatively about 150° C. to 275° C. for of about 0.5 to 5 minutes, alternatively about 200° C. to 250° C. for about 0.5 to 2 minutes. Any method of heating known to those skilled in the art may be used during the curing step 230. For example, the coated electronic device may be placed in a quartz tube furnace, convection oven or allowed to stand on hot plates.

To protect the silsesquioxane resin in the ARC material from reactions with oxygen or carbon during curing, the curing step can be optionally performed under an inert atmosphere (235) when desired. This optional step (235) may be conducted alone or along with the incorporation of desired additives (210) into the ARC material. Inert atmospheres useful herein include, but are not limited to, nitrogen and argon. By “inert” it is meant that the environment contain less than about 50 ppm and alternatively less than about 10 ppm of oxygen. The pressure at which the curing and removal steps are carried out is not critical. The curing step 230 is typically carried out at atmospheric pressure although sub or super atmospheric pressures may work also.

Typically the antireflective coating after cure is insoluble in photoresist casting solvents. These solvents include, but are not limited to, esters and ethers such as propylene glycol methyl ether acetate (PGMEA) and ethoxy ethyl propionate (EPP). By insoluble it is meant that when the antireflective coating is exposed to the solvent, there is little or no loss in the thickness of the coating after exposure for 1 minute. Typically the loss in the thickness of the coating is less than 10% of the coating thickness, alternatively less than 7.5% of the coating thickness.

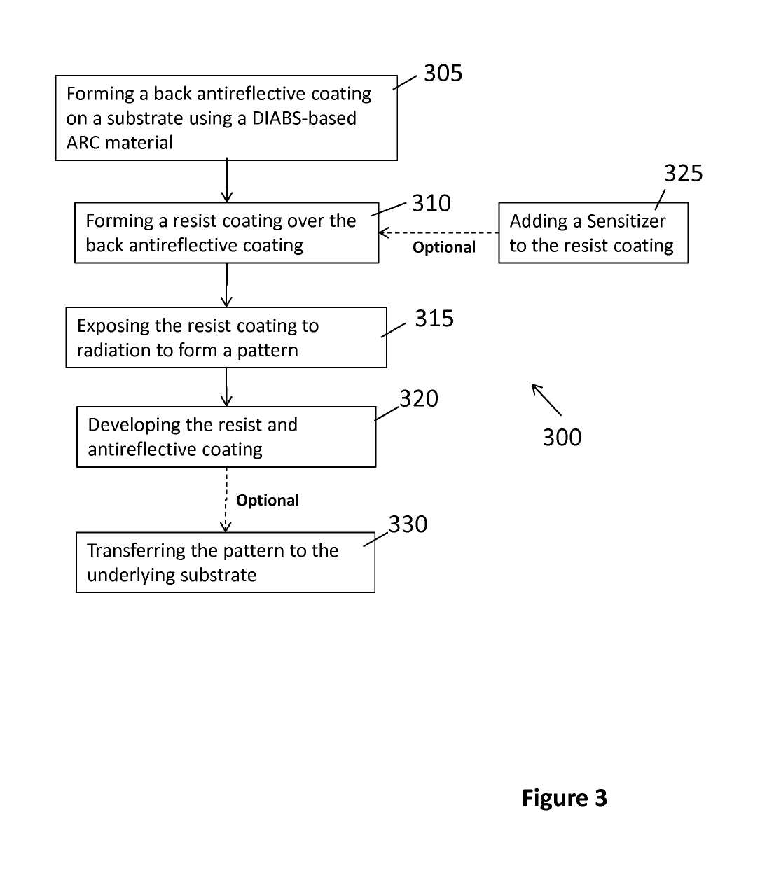

According to another aspect of the present disclosure, a photolithographic process that uses a bottom antireflective coating (BARC) formed from a DIABS-based ARC material is provided. Referring to FIG. 3, this process 300 generally comprises the steps of: forming a BARC on a substrate, such as an electronic device (305); forming a resist coating over the antireflective coating (310); exposing the resist to radiation (315); and developing the resist and the antireflective coating (320). The DIABS-based ARC material used to form the BARC is prepared according to method 100 of the present disclosure and applied to the substrate according to the process 200 described herein.

A resist coating or layer is formed over the antireflective coating (310). This resist layer can be formed using any known resist materials and method for forming such a coating known to one skilled in the art. Typically the resist materials are applied from a solvent solution in a manner similar to producing the antireflective coating herein. The resist coating may be baked to remove any solvent. Depending on the source used for baking, the baking typically occurs by heating the coating to a temperature of 90° C. to 130° C. for several minutes to an hour or more.

After the resist layer is formed, it is then exposed to radiation (315), i.e., UV, X-ray, e-beam, EUV, or the like, so that a pattern is formed. Typically ultraviolet radiation having a wavelength of 157 nm to 365 nm are used, alternatively, ultraviolet radiation having a wavelength of 157 nm or 193 nm is used. Suitable radiation sources include mercury, mercury/xenon, and xenon lamps. Alternatively the radiation source is a KrF excimer laser (248 nm) or an ArF excimer laser (193 nm). If longer wavelength radiation is used, e.g., 365 nm, one may optionally add a sensitizer to the resist coating to enhance absorption of the radiation (325). Full exposure of the resist coating is typically achieved with less than 100 mJ/cm² of radiation, alternatively with less than 50 mJ/cm² of radiation. Typically, the resist layer is exposed through a mask; thereby, a pattern is formed on the coating.

Upon exposure to radiation, the radiation is absorbed by the acid generator in the resist coating, which generates free acid. When the resist coating is a positive resist, upon heating, the free acid causes cleavage of acid dissociable groups of the resist. When the resist coating is a negative resist, the free acid causes the cross-linking agents to react with resist, thereby forming insoluble areas of exposed resist. After the resist layer has been exposed to radiation, the resist layer typically undergoes a post-exposure bake, wherein the resist layer is heated to a temperature in the range of 30° C. to 200° C., alternatively 75° C. to 150° C. for a short period of time, typically 30 seconds to 5 minutes, alternatively 60 to 90 seconds.

The exposed resist and antireflective coatings are removed with a suitable developer or stripper solution to produce an image (320). The antireflective coatings may be removed at the same time that the exposed resist coating is removed, thereby eliminating the need for a separate etch step to remove the antireflective coating. Suitable developer solutions typically contain an aqueous base solution, preferably an aqueous base solution without metal ions, and optionally an organic solvent. One skilled in the art will be able to select the appropriate developer solution. Standard industry developer solutions may be exemplified by, but not limited to, inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide and choline, and cyclic amines such as pyrrole and piperidine. Alternatively, solutions of a quaternary ammonium salt, such as tetramethylammonium hydroxide (TMAH) or choline are used. Suitable fluoride-based stripping solutions include, but are not limited to, ACT® NE-89 (Ashland Specialty Chemical Co.). After the exposed coating has been developed, the remaining resist coating (“pattern”) is typically washed with water to remove any residual developer solution.

The pattern produced in the resist and antireflective coatings or layers may then be optionally transferred to the material of the underlying substrate (330). In coated or bilayer photoresists, this will involve transferring the pattern through the coating that may be present and through the underlayer onto the base layer. In single layer photoresists, the transfer will be made directly to the substrate. Typically, the pattern is transferred by etching with reactive ions such as oxygen, plasma, and/or oxygen/sulfur dioxide plasma. Suitable plasma tools include, but are not limited to, electron cyclotron resonance (ECR), helicon, inductively coupled plasma, (ICP) and transmission-coupled plasma (TCP) system. Etching techniques are well known in the art and one skilled in the art will be familiar with the various types of commercially available etching equipment. Additional steps or removing the resist film and remaining antireflective coating may be employed to produce a device having the desired architecture.

The following specific examples are given to illustrate the disclosure and should not be construed to limit the scope of the disclosure. Those skilled-in-the-art, in light of the present disclosure, will appreciate that many changes can be made in the specific embodiments which are disclosed herein and still obtain alike or similar result without departing from or exceeding the spirit or scope of the disclosure.

Several silsesquioxane resin solutions (Runs 1-1, 1-2, 3-1, and 3-2) were conventionally prepared according to Examples 1 and 3, while several DIABS-based resin solutions (Runs 2-1, 2-2, 4-1, and 4-2) were prepared according to the teachings of the present disclosure as further described in Examples 2 and 4. The stability of the conventional and DIABS-based silsesquioxane resins (in 10% PGMEA) were monitored by a change in molecular weight at room temperature with the results being summarized in Tables 1 and 2.

In each run, the silsesquioxane resins were applied as a coating to wafers using a Karl Suss CT62 spin coater (SUSS MicroTec AG, Garching Germany). The silsesquioxane resin-PGMEA solutions were first filtered through a 0.2 mm TEFLON® filter and then spin coated onto standard single side four inch polished low resistivity wafers or double sided polished FTIR wafers at a spin speed of 2000 rpm with an acceleration speed of 5000 over a time frame of 20 seconds. The applied films were subsequently dried and then cured at 250° C. for 60 seconds using a rapid thermal processing (RTP) oven with a nitrogen gas purge. The film thickness of each applied ARC was determined using an ellipsometer (J. A. Woollam, Lincoln, Neb.). The thickness values recorded in Tables 1 and 2 represent the average of nine measurements. PGMEA resistance after cure was determined by measuring the film thickness change before and after being exposed to a PGMEA rinse. Contact angle measurements were conducted using water and methylene iodide as liquids and the critical surface tension of wetting was calculated based on the Zisman approach.

TABLE 1
The Comparison of Silsequioxane Resins Having the General
Composition of Q/Me/BTSE in the Ratio of 58/37/5.

| | | | | Mw % | | | | |
|---|---|---|---|---|---|---|---|---|
| | | | | change | | | | |
| | Q | Initial MW | | per day | Thickness | | PGMEA | TMAH |
| Run # | Monomer | Mw | PDI | @ 23° C. | (Å) | SD | Loss (Å) | Loss (Å) |
| 1-1 | TEOS | 7990 | 3.03 | 3.9% | 1953 | 10 | −4 | 33 |
| 1-2 | TEOS | 10300 | 3.43 | 3.6% | 1986 | 4 | −1 | 23 |
| 2-1 | DIABS | 15100 | 3.77 | 1.3% | 2051 | 13 | 10 | 122 |
| 2-2 | DIABS | 4820 | 2.39 | 1.1% | 1448 | 34 | 16 | 115 |

TABLE 2
The Comparison of Silsesquioxane Resins Having the General
Composition of Q/Me/BTSE/PhEt in the Ratio of 65/20/10/5.

| | | | | Mw % | | | | |
|---|---|---|---|---|---|---|---|---|
| | | | | change | | | | |
| | Q | Initial MW | | per day | Thickness | | PGMEA | TMAH |
| Run # | Monomer | Mw | PDI | @ 23° C. | (Å) | SD | Loss (Å) | Loss (Å) |
| 5 | TEOS | 19900 | 5.35 | 8.4% | 1810 | 8 | −6 | 26 |
| 6 | TEOS | 9350 | 3.20 | 67.7% | 1969 | 9 | 6 | 30 |
| 7 | DIABS | 5230 | 2.37 | 1.0% | 1274 | 24 | 8 | 182 |
| 8 | DIABS | 17300 | 3.99 | 1.0% | 1793 | 16 | 34 | 165 |

Upon comparison of the properties exhibited by the DIABS-based silsesquioxane resins (Runs 2-1, 2-2, 4-1, and 4-2) with the properties exhibited by conventional silsequioxane resins prepared via the use of TEOS monomers (Runs 1-1, 1-2, 3-1, and 3-2), the DIABS-based silsesquioxane compositions demonstrate outstanding optical, mechanical and etch properties, as well as great shelf-life and stability on storage; and good film quality with excellent solvent (e.g. PGMEA) and developer (e.g., TMAH) resistance. As shown in Tables 1 and 2, the DIABS-based silsesquioxane resins (Runs 2-1, 2-2, 4-1, and 4-2) exhibit only a small change (about 1%) in molecular weight per day upon storage at 23° C., while the conventional silsequioxane resins (Runs 1-1, 1-2, 3-1, and 3-2) exhibit a large change in molecular weight in the range of 3.6% to 67.7% under similar conditions. Thus the DIABS-based silsesquioxane resins exhibit greater stability upon storage and a longer shelf-life. Upon exposure to PGMEA and/or TMAH, the DIABS-based silsesquioxane resins exhibit excellent stability and outstanding etch properties.

### Example 1

### Preparation of Conventional Silsequioxane Resins Having a Ratio of TEOS/Me/BTSE Equal to 58/37/5

To a dry 1-liter three-necked flask equipped with a stir bar were added methyltriethoxysilane (66.0 g, 0.37 mol), bis(triethoxysilyl)ethane (BTSE) (17.8 g, 0.05 mol), tetraethylorthosilicate (TEOS) (120.8 grams, 0.58 mol), propylene glycol monomethylether acetate (PGMEA) (50 g) and a small amount of nitric acid. Water (50 g) dissolved in PGMEA was added to the three-necked flask over 60 minutes using a peristaltic pump. After the addition, the mixture was heated to reflux for several hours. The volatiles were then stripped using a rotary evaporator and the final concentration of the resin in the solution was adjusted to 10 wt. % by adding PGMEA. The resulting solution was filtered through a 0.2 mm Teflon® filter. The solution was spun on a 4″-wafer, cured, and tested as Runs 1-1 and 1-2. The cured coatings exhibited n_{@193 nm}=1.519 and k_{@193 nm}=0.00.

### Example 2

### Preparation of DIABS-based Silsequioxane Resins Having a Ratio of DIABS/Me/BTSE Equal to 58/37/5

To a dry 1-liter three-necked flask equipped with a stir bar were added methyltriethoxysilane (66.0 g, 0.37 mol), bis(triethoxysilyl)ethane (BTSE) (17.8 g, 0.05 mol), di-t-butoxydiacetoxysilane (DIABS) (170.0 g, 0.58 mol), propylene glycol monomethylether acetate (PGMEA) (50 g) and a small amount of nitric acid. Water (50 g) dissolved in PGMEA was added to the three-necked flask over 60 minutes using a peristaltic pump. After the addition, the mixture was heated to reflux for several hours. The volatiles were then stripped using a rotary evaporator and the final concentration of the resin in solution was adjusted to 10 wt. % by adding PGMEA. The resulting solution was filtered through a 0.2 mm Teflon® filter. The solution was spun onto a 4″-wafer, cured, and tested. The cured coatings exhibited n_{@193 nm}=1.526 and k_{@193 nm}=0.

### Example 3

### Preparation of Conventional Silsequioxane Resins Having a Ratio of TEOS/BTSE/Me/PhEt Equal to 65/20/10/5

To a dry 1-liter three-necked flask equipped with a stir bar were added methyltriethoxysilane (17.8 g, 0.10 mol), bis(triethoxysilyl)ethane (BTSE) (70.9 g, 0.20 mol), phenethyltrimethoxysilane (11.4 g, 0.05 mol), tetraethylorthosilicate (TEOS) (135.2 g, 0.65 mol), propylene glycol monomethylether acetate (PGMEA) (50 g) and a small amount of nitric acid. Water (50 g) dissolved in PGMEA was added to the three-necked flask over 60 minutes using a peristaltic pump. After the addition, the mixture was heated to reflux for several hours. The volatiles were then stripped using a rotary evaporator and the final concentration of the resin in solution was adjusted to 10 wt % by adding PGMEA. The resulting solution was filtered through a 0.2 mm Teflon® filter. The solution was spun onto a 4″-wafer, cured, and tested as Runs 3-1 and 3-2. The cured coatings exhibited n_{@193 nm}=1.610 and k_{@193 nm}=0.152.

### Example 4

### Preparation of DIABS-based Silsequioxane Resins Having Ratio of DIABS/BTSE/Me/PhEt Equal to 65/20/10/5

To a dry 1-liter three-necked flask equipped with a stir bar were added methyltriethoxysilane (17.8 g, 0.10 mol), bis(triethoxysilyl)ethane (BTSE) (70.9 g, 0.20 mol), phenethyltrimethoxysilane (11.4 g, 0.05 mol), di-t-butoxydiacetoxysilane (DIABS) (190.1 g, 0.65 mol), propylene glycol monomethylether acetate (PGMEA) (50 g) and a small amount of nitric acid. Water (50 g) dissolved in PGMEA was added to the three-necked flask over 60 minutes using a peristaltic pump. After the addition, the mixture was heated to reflux for several hours. The volatiles were then stripped using a rotary evaporator and the final concentration of the resin in solution was adjusted to 10 wt. % by adding PGMEA. The resulting solution was filtered through a 0.2 mm Teflon® filter. The solution was spun onto a 4″-wafer, cured, and tested as Runs 4-1 and 4-2. The cured coatings exhibited n_{@193 nm}=1.602 and k_{@193 nm}=0.159.

A person skilled in the art will recognize that the measurements described are standard measurements that can be obtained by a variety of different test methods. The test methods described in the examples represents only one available method to obtain each of the required measurements.

The foregoing description of various embodiments of the present disclosure has been presented for purposes of illustration and description. It is not intended to be exhaustive or to limit the present disclosure to the precise embodiments disclosed.

Numerous modifications or variations are possible in light of the above teachings. The embodiments discussed were chosen and described to provide the best illustration of the principles included in the present disclosure and its practical application to thereby enable one of ordinary skill in the art to utilize the teachings of the present disclosure in various embodiments and with various modifications as are suited to the particular use contemplated. All such modifications and variations are within the scope of the present disclosure as determined by the appended claims when interpreted in accordance with the breadth to which they are fairly, legally, and equitably entitled.

What is claimed is:

1. A method for preparing a di-t-butoxydiacetoxysilane (DIABS)-based silsesquioxane resin for use in a hard-mask antireflective coating for photolithography, the method comprising the steps of:
a) providing silane monomers including DIABS and at least one selected from the group of R¹ SiX₃, R²SiX₃, R³SiX₃, and SiX₄, in a solvent to form a reaction mixture; wherein R¹ is H or an alkyl group, X is a halide or an alkoxy group, R² is a chromophore moiety, and R³ is a reactive site or crosslinking site;
b) allowing hydrolysis and condensation reactions to occur to form structural units in the DIABS-based silsesquioxane resin by adding water to the reaction mixture over a predetermined amount of time and at a predetermined temperature; and
c) forming a DIABS-based silsesquioxane resin solution with at least one structural unit being an SiO_{4/2} unit arising from the hydrolysis and condensation of the DIABS monomers;
optionally d) adding a catalyst to the reaction mixture, the catalyst being a mineral acid selected as one from the group of HCl, HF, HBr, HNO₃, and H₂SO₄;
and optionally followed by the step of removing or neutralizing the catalyst from the DIABS-based silsesquioxane resin solution.

2. The method according to claim 1, wherein the method further comprises the step of bodying in which the hydrolysis and condensation reactions are allowed to continue in order to increase the molecular weight of the DIABS-based silsesquioxane resin.

3. The method according to claim 1, wherein the method further comprises the step of exchanging the solvent with a different solvent.

4. The method according to claim 1, wherein the method further comprises the step of removing the solvent and collecting the DIABS-based silsesquioxane resin.

5. A method of preparing an antireflective coating for use in photolithography, the method comprising the steps of:
a) providing a di-t-butoxydiacetoxy-silane (DIABS)-based silsesquioxane resin dispersed in a solvent to form an ARC material; the DIABS-based silsequioxane resin comprising structural units formed from the hydrolysis and condensation of silane monomers including DIABS and at least one selected from the group of R¹SiX₃, R²SiX₃, R³SiX₃, and SiX₄ with water; wherein R¹ is H or an alkyl group, X is a halide or an alkoxy group, R² is a chromophore moiety, R³ is a reactive site or crosslinking site, and wherein at least one structural unit is an SiO_{4/2} unit arising from the hydrolysis and condensation of the DIABS monomers;
b) providing an electronic device;
c) applying the ARC material to the surface of the electronic device to form a film;
d) removing the solvent from the film;
e) curing the film to form the antireflective coating; and
optionally further comprising the step of:
f) incorporating additives into the ARC material; or
g) placing the film under an inert atmosphere prior to curing the film; or
h) both steps f) and g).

6. The method according to claim 5, wherein the ARC material is applied to the surface of the electronic device by spin-coating.

7. A method of performing photolithography using a DIABS-based silsequioxane resin in an antireflective coating, the method comprising the steps of:
a) forming a antireflective coating on a substrate, the antireflective coating comprising a DIABS-based silsequioxane resin having structural units formed from the hydrolysis and condensation of silane monomers including di-t-butoxydiacetoxysilane (DIABS) and at least one selected from the group of R¹ SiX₃, R²SiX₃, R³SiX₃, and SiX₄ with water; wherein R¹ is H or an alkyl group, X is a halide or an alkoxy group, R² is a chromophore moiety, R³ is a reactive site or crosslinking site, and wherein at least one structural unit is an SiO_{4/2} unit arising from the hydrolysis and condensation of the DIABS monomers;
b) forming a resist coating over the antireflective coating
c) exposing the resist to radiation to form a pattern on the resist; and
d) developing the resist and the antireflective coating; and optionally
e) transferring the pattern to the underlying substrate; or
f) adding a sensitizer to the resist coating; or
g) both steps e) and f).

8. The method according to claim 7, wherein the antireflective coating is formed on the substrate by spin-coating.

9. The method according to claim 8, wherein the solvent in which the monomers are provided is an organic or a silicone solvent.

10. The method according to claim 9, wherein the organic solvent is propylene glycol monomethyl ethyl acetate (PGMEA).

11. The method according to claim 10, wherein the silane monomers includes at least one wherein X is a Cl, OEt, or OMe group.

12. The method according to claim 11, wherein the silane monomers includes at least one wherein the R² chromophore moiety is a phenyl or substituted phenyl group.

13. The method according to claim 7, wherein the structural units of the DIABS-based silsesquioxane resin formed from the hydrolysis and condensation of silane monomers are defined according to the relationship:
[(SiO_{(4-x)/2}(OR)ₓ)]ₘ[(Ph(CH₂)ᵣSiO_{(3-x)/2}(OR)ₓ]ₙ[(RO)ₓO_{(3-x)/2}Si—CH₂CH₂—SiO_{(3-x)/2}(OR)ₓ]ₒ[R′SiO_{(3 x)/2}(OR)ₓ]ₚ;
wherein the subscripts m, n, o, and p represent the mole fraction of each structural unit with each subscript being independently selected to range between 0 and 0.95, provided that the sum of the subscripts (m+n+o+p) is equal to 1;
wherein R is independently selected as a t-butyl group, a hydrogen, or a hydrocarbon group having from 1 to 4 carbon atoms; Ph is a phenyl group; and
R′ is independently selected as a hydrocarbon group, a substituted phenyl group, an ester group, a polyether group, a mercapto group, or a reactive (e.g., curable) organic functional group; and
wherein the subscripts r and x are independently selected such that r has a value of 0, 1, 2, 3, or 4 and x has a value of 0, 1, 2, or 3.

14. The method of claim 13, wherein the [(SiO_{(4-x)/2}(OR)ₓ)]ₘ structural unit is formed from the hydrolysis and condensation of the DIABS monomers.

15. A DIABS-based silsequioxane resin, the resin comprising components A, B, C, and D according to the relationship or formula [A]ₘ[B]ₙ[C]ₒ[D]ₚ with the subscripts m, n, o, and p representing the mole fraction of each component in the resin; each subscript being independently selected to range between 0 and 0.95, provided that the sum of the subscripts (m+n+o+p) is equal to 1;
wherein component A represents structural units of [(SiO_{(4-x)/2}(OR)ₓ)], component B represents structural units of [(Ph(CH₂)ᵣ SiO_{(3-x)/2}(OR)ₓ], component C represents structural units of [(RO)ₓO_{(3-x)/2}Si—CH₂CH₂—SiO_{(3-x)/2}(OR)ₓ], and component D represents structural units of [R′SiO_{(3-x)/2}(OR)ₓ]; R is independently selected as a t-butyl group, a hydrogen, or a hydrocarbon group having from 1 to 4 carbon atoms; Ph is a phenyl group; R′ is independently selected as a hydrocarbon group, a substituted phenyl group, an ester group, a polyether group, a mercapto group, or a reactive (e.g., curable) organic functional group; and the subscripts r and x are independently selected such that r has a value of 0, 1, 2, 3, or 4 and x has a value of 0, 1, 2, or 3;
wherein the resin is formed according to the method of claims 1-11 such that at least one structural unit arises from the hydrolysis and condensation of the DIABS monomers.

16. The DIABS-based silsesquioxane resin of claim 15, wherein the structural unit of component A is formed from the hydrolysis and condensation of the DIABS monomers.

17. The method according to claim 1, wherein the solvent in which the monomers are provided is an organic or a silicone solvent.

18. The method according to claim 17, wherein the organic solvent is propylene glycol monomethyl ethyl acetate (PGMEA).

19. The method according to claim 1, wherein the silane monomers includes at least one wherein X is a Cl, OEt, or OMe group.

20. The method according to claim 1, wherein the silane monomers includes at least one wherein the R² chromophore moiety is a phenyl or substituted phenyl group.

21. The method according to claim 1, wherein the structural units of the DIABS-based silsesquioxane resin formed from the hydrolysis and condensation of silane monomers are defined according to the relationship:
[(SiO_{(4-x)/2}(OR)ₓ)]ₘ[(Ph(CH₂)ᵣSiO_{(3-x)/2}(OR)ₓ]ₙ[(RO)ₓO_{3-x)/2}Si—CH₂CH₂—SiO_{(3-x)/2}(OR)ₓ]ₒ[R′SiO_{(3 x)/2}(OR)ₓ]ₚ;
wherein the subscripts m, n, o, and p represent the mole fraction of each structural unit with each subscript being independently selected to range between 0 and 0.95, provided that the sum of the subscripts (m+n+o+p) is equal to 1;
wherein R is independently selected as a t-butyl group, a hydrogen, or a hydrocarbon group having from 1 to 4 carbon atoms; Ph is a phenyl group; and R′ is independently selected as a hydrocarbon group, a substituted phenyl group, an ester group, a polyether group, a mercapto group, or a reactive (e.g., curable) organic functional group; and
wherein the subscripts r and x are independently selected such that r has a value of 0, 1, 2, 3, or 4 and x has a value of 0, 1, 2, or 3.

22. The method of claim 21, wherein the [(SiO_{(4-x)/2}(OR)ₓ)]ₘ structural unit is formed from the hydrolysis and condensation of the DIABS monomers.
